(19) United States
(12) Patent Application Publication
(10) Pub. No.: US 2026/0239959 A1
(43) Pub. Date: Aug. 13, 2026

(54) SEMICONDUCTOR DEVICE

(71) Applicant: Mitsubishi Electric Corporation, Tokyo (JP)

(72) Inventors: Hideo KOMO, Tokyo (JP); Fumio WADA, Tokyo (JP); Kazuhiro NISHIMURA, Fukuoka (JP)

(73) Assignee: Mitsubishi Electric Corporation, Tokyo (JP)

(21) Appl. No.: 19/471,245

(22) PCT Filed: May 24, 2023
(86) PCT No.: PCT/JP2023/019286

§ 371 Date: Sep. 30, 2025

(51) Int. Cl. H10W 40/22; H10W 40/20

(52) U.S. Cl. CPC H10W 40/22; H10W 40/233

(57) ABSTRACT

An object is to reliably supply a bonding material to a groove on a cooling plate provided immediately below a corner part of an insulating substrate. A semiconductor device includes an insulating substrate and a cooling plate. The insulating substrate holds a semiconductor chip. The cooling plate holds the insulating substrate. The cooling plate includes a groove. The groove is provided along at least a part of a peripheral edge part of the insulating substrate in a plan view. The groove includes a flat part in which a bottom surface of the groove is flat and an inclination part including a downward inclination in which the bottom surface of the groove is inclined toward the flat part. The flat part is provided to be overlapped with a corner part of the insulating substrate included in the peripheral edge part of the insulating substrate in a plan view.

### TECHNICAL FIELD

The present disclosure relates to a semiconductor device.

### BACKGROUND ART

A semiconductor device includes a heat radiation plate for radiating heat generated in a semiconductor chip. A heat radiation plate of a semiconductor device described in Patent Document 1 includes an L-like concave part (having a “<”-like shape). The concave part ensures a thickness of a solder layer in a corner part of an insulating substrate. Reduced is a possibility of detachment of the solder layer between a conductive pattern of the insulating substrate and the heat radiation plate, and heat radiation properties of the semiconductor chip is improved.

### PRIOR ART DOCUMENTS

### Patent Document(s)

Patent Document 1: Japanese Patent Application Laid-Open No. 2009-188164

### SUMMARY

### Problem to be Solved by the Invention

When the groove is provided only immediately below four corner parts of the insulating substrate, a supply amount of the solder to the groove may be insufficient.

In order to solve the above problems, an object of the present disclosure is to provide a semiconductor device capable of reliably supplying a bonding material to a groove on a cooling plate provided immediately below a corner part of an insulating substrate.

### Means to Solve the Problem

A semiconductor device according to the present disclosure includes an insulating substrate and a cooling plate. The insulating substrate holds a semiconductor chip. The cooling plate holds the insulating substrate. The cooling plate includes a groove. The groove is provided along at least a part of a peripheral edge part of the insulating substrate in a plan view. The groove includes a flat part in which a bottom surface of the groove is flat and an inclination part including a downward inclination in which the bottom surface of the groove is inclined toward the flat part. The flat part is provided to be overlapped with a corner part of the insulating substrate included in the peripheral edge part of the insulating substrate in a plan view.

### Effects of the Invention

According to the present disclosure, provided is a semiconductor device capable of reliably supplying a bonding material to a groove on a cooling plate provided immediately below four corners of an insulating substrate.

These and other objects, features, aspects and advantages of the present disclosure will become more apparent from the following detailed description of the present disclosure when taken in conjunction with the accompanying diagrams.

### BRIEF DESCRIPTION OF DRAWINGS

FIG. 1 is a perspective view illustrating a configuration of a semiconductor device according to an embodiment 1.

FIG. 2 is a plan view illustrating a configuration of the semiconductor device.

FIG. 3 is a cross-sectional view illustrating a configuration of the semiconductor device.

FIG. 4 is a perspective view illustrating a configuration of a cooling plate.

FIG. 5 is a plan view illustrating a configuration of a semiconductor device according to an embodiment 2.

FIG. 6 is a perspective view illustrating a configuration of a cooling plate of the semiconductor device.

FIG. 7 is a perspective view illustrating a configuration of a cooling plate of a semiconductor device according to an embodiment 3.

FIG. 8 is a plan view illustrating a configuration of the cooling plate.

FIG. 9 is a plan view illustrating a configuration of a semiconductor device according to an embodiment 4.

FIG. 10 is a plan view illustrating a configuration of a semiconductor device according to an embodiment 5.

FIG. 11 is a plan view illustrating a configuration of a semiconductor device according to an embodiment 6.

FIG. 12 is a plan view illustrating a configuration of a semiconductor device according to a modification example of the embodiment 6.

FIG. 13 is a cross-sectional view illustrating a configuration of a semiconductor device according to an embodiment 7.

FIG. 14 is a cross-sectional view illustrating a configuration of a semiconductor device according to a modification example of the embodiment 7.

FIG. 15 is a cross-sectional view illustrating a configuration of a semiconductor device according to the modification example of the embodiment 7.

### DESCRIPTION OF EMBODIMENT(S)

### Embodiment 1

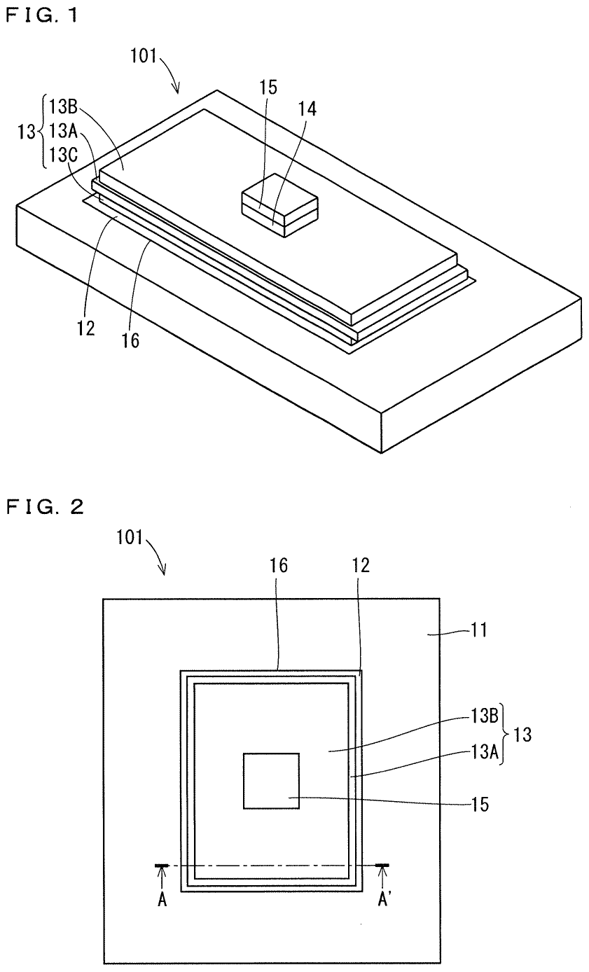

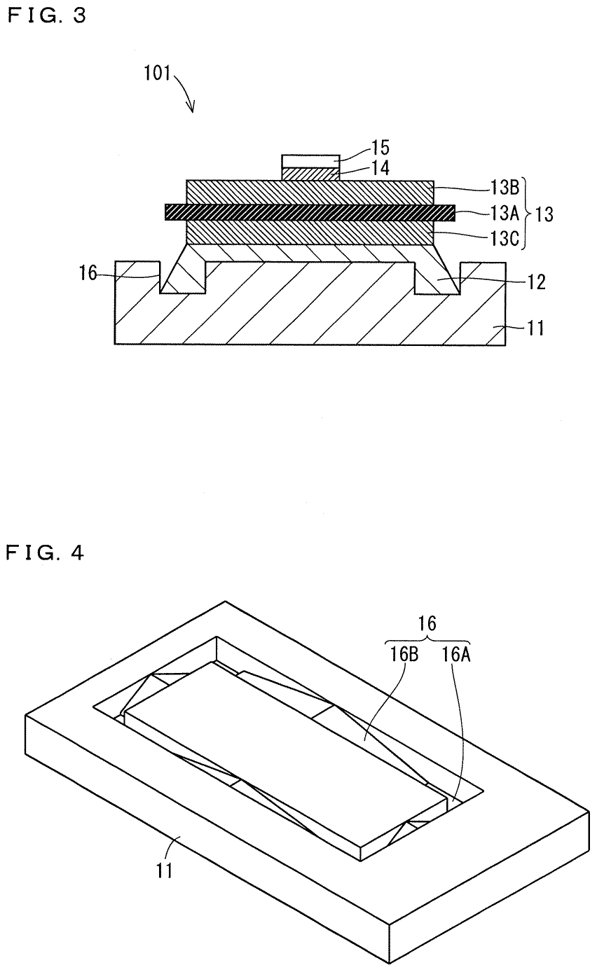

FIG. 1 is a perspective view illustrating a configuration of a semiconductor device 101 according to an embodiment 1. FIG. 2 is a plan view illustrating the configuration of the semiconductor device 101. FIG. 3 is a cross-sectional view illustrating the configuration of the semiconductor device 101. FIG. 3 illustrates a cross section along A-A′ illustrated in FIG. 2.

The semiconductor device 101 includes a cooling plate 11, a first bonding material 12, an insulating substrate 13, a second bonding material 14, and a semiconductor chip 15.

The cooling plate 11 holds the insulating substrate 13. The cooling plate 11 is a plate formed of metal such as Cu or Al or a plate formed of an AlSiC combined material, for example. The cooling plate 11 has a function of transmitting heat generated in an electrical component such as the semiconductor chip 15 to an outer part.

FIG. 4 is a perspective view illustrating a configuration of the cooling plate 11. The cooling plate 11 includes a groove 16. The groove 16 according to the embodiment 1 is provided along a whole peripheral edge part of the insulating substrate 13 in a plan view. Since the insulating substrate 13 has a rectangular shape in a plan view as described hereinafter, the groove 16 extends to form an annular rectangular shape. The groove 16 includes a flat part 16A and an inclination part 16B.

The flat part 16A is provided to be overlapped with a corner part included in the peripheral edge part of the insulating substrate 13 in a plan view. A bottom surface of the groove 16 in the flat part 16A is flat, that is to say, parallel to a lower surface of the cooling plate 11. In the embodiment 1, four flat parts 16A are provided. Positions of four flat parts 16A correspond to positions of four corner parts of the insulating substrate 13. A planar shape of the flat part 16A has an L-like shape.

The inclination part 16B is provided along the peripheral edge part of the insulating substrate 13 other than the corner part in a plan view. The bottom surface of the groove 16 in the inclination part 16B includes a downward inclination inclined toward the flat part 16A. A bottom surface of the inclination part 16B includes a top in a midpoint of the inclination part 16B in an extension direction of the groove 16. In the embodiment 1, four inclination parts 16B are provided. Two of the four inclination parts 16B are provided along a long side of the insulating substrate 13. The remaining two inclination parts 16B are provided along a short side of the insulating substrate 13.

The first boning material 12 bonds the cooling plate 11 and the insulating plate 13. The first boning material 12 is provided between the cooling plate 11 and the insulating plate 13. A part of the bonding material is also provided to the groove 16. The first bonding material 12 is solder or a sintering material, for example. The sintering material includes Ag or Cu, for example.

The insulating substrate 13 holds the semiconductor chip 15. A planar shape of the insulating substrate 13 is a rectangular shape. The insulating substrate 13 includes a substrate body 13A, a front surface metal pattern 13B, and a back surface metal pattern 13C. The substrate body 13A is formed of ceramic, for example. The substrate body 13A has a rectangular shape in a plan view. The front surface metal pattern 13B is provided on an upper surface of the substrate body 13A. The back surface metal pattern 13C is provided on a lower surface of the substrate body 13A. The front surface metal pattern 13B and the back surface metal pattern 13C are formed of metal such as Cu or Al, for example. The back surface metal pattern 13C is bonded to the cooling plate 11 via the first bonding material 12.

The second boning material 14 bonds the insulating plate 13 and the semiconductor chip 15. The second boning material 14 is provided between the insulating plate 13 and the semiconductor chip 15. The second bonding material 14 is solder or a sintering material, for example. The sintering material includes Ag or Cu, for example.

The semiconductor chip 15 is bonded to the front surface metal pattern 13B of the insulating substrate 13 via the second bonding material 14. The semiconductor chip 15 is formed of semiconductor such as Si, for example. The semiconductor is preferably so-called wide bandgap semiconductor such as SiC, GaN, Ga₂O₃, or diamond. The semiconductor chip 15 is a power semiconductor chip or a control integrated circuit (IC) for controlling the power semiconductor chip, for example. The semiconductor chip 15 according to the embodiment 1 includes a vertical semiconductor element in which current flows between an upper surface and a lower surface thereof. The semiconductor element is an insulated gate bipolar transistor (IGBT), a metal oxide semiconductor field effect transistor (MOSFET), or a Schottky barrier diode, for example. The semiconductor element may be a reverse-conducting IGBT (RC-IGBT) in which an IGBT and a reflux diode are formed in one semiconductor chip 15.

To sum up the above, the semiconductor device 101 according to the embodiment 1 includes the insulating substrate 13 and the cooing plate 11. The insulating substrate 13 holds the semiconductor chip 15. The cooling plate 11 holds the insulating substrate 13. The cooling plate 11 includes the groove 16. The groove 16 is provided along at least a part of the peripheral edge part of the insulating substrate 13 in a plan view. The groove 16 includes the flat part 16A in which the bottom surface of the groove 16 is flat and the inclination part 16B including the downward inclination in which the bottom surface of the groove 16 is inclined toward the flat part 16A. The flat part 16A is provided to be overlapped with the corner part of the insulating substrate 13 included in the peripheral edge part of the insulating substrate 13 in a plan view. The groove 16 according to the embodiment 1 is provided along the whole peripheral edge part of the insulating substrate 13 in a plan view.

In a process of manufacturing the semiconductor device 101 having such a configuration, the first bonding material 12 in a melting state easily flows into the flat part 16A through the inclination part 16B of the groove 16. Thus, a thickness of the first bonding material 12 immediately below the corner part of the insulating substrate 13 is sufficiently ensured. Although stress is easily concentrated in the first bonding material 12 immediately below the corner part, the thickness of the first bonding material 12 is sufficiently ensured; thus, reliability of the first bonding material 12 is improved. For example, the first bonding material 12 is hardly detached.

The semiconductor device 101 is used for a power control apparatus, for example. When the semiconductor chip 15 is formed of SiC, the semiconductor device 101 is operated at a high temperature. Thus, although stress occurring in the corner part of the insulating substrate 13 increases, the thickness of the first bonding material 12 is sufficiently ensured by the groove 16 described above; thus, reliability of the semiconductor device 101 is improved.

### Embodiment 2

In an embodiment 2, the same reference numerals are assigned to constituent elements similar to those in the embodiment 1, and the detailed description thereof is omitted.

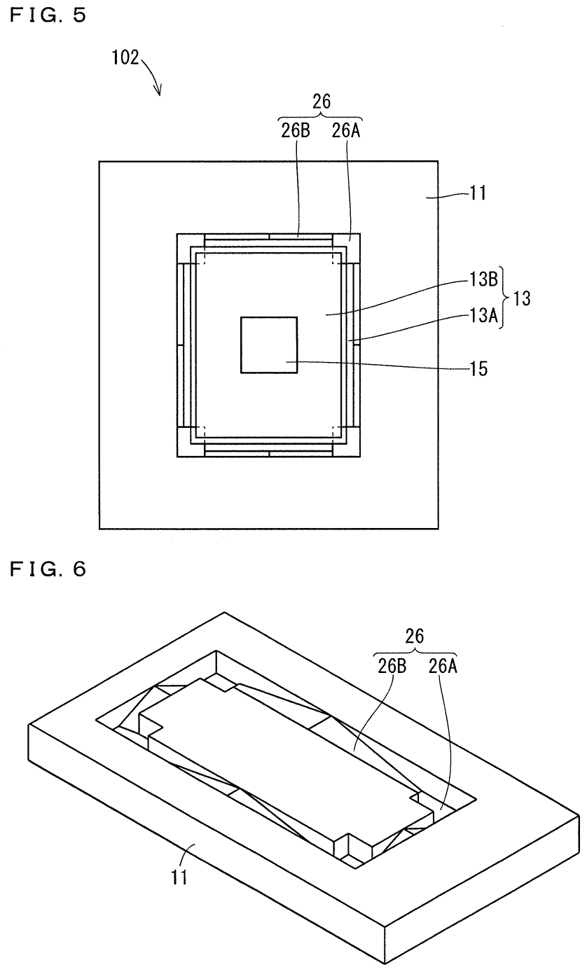

FIG. 5 is a plan view illustrating a configuration of a semiconductor device 102 according to the embodiment 2. Illustration of the first bonding material 12 is omitted in FIG. 5. FIG. 6 is a perspective view illustrating a configuration of the cooling plate 11 of the semiconductor device 102. The cooling plate 11 includes a groove 26. The groove 26 includes a flat part 26A and an inclination part 26B.

The flat part 26A is provided to be overlapped with the corner part of the insulating substrate 13 in a plan view in the manner similar to the embodiment 1. A planar shape of the flat part 26A is a rectangular shape. The inclination part 26B is provided along the peripheral edge part of the insulating substrate 13 other than the corner part in the manner similar to the embodiment 1. A groove width of the flat part 26A according to the embodiment 2 is larger than that of the inclination part 26B.

According to such a configuration, in a process of manufacturing the semiconductor device 102, the first bonding material 12 is easily supplied to the flat part 26A.

### Embodiment 3

In an embodiment 3, the same reference numerals are assigned to constituent elements similar to those in the embodiment 1 or 2, and the detailed description thereof is omitted.

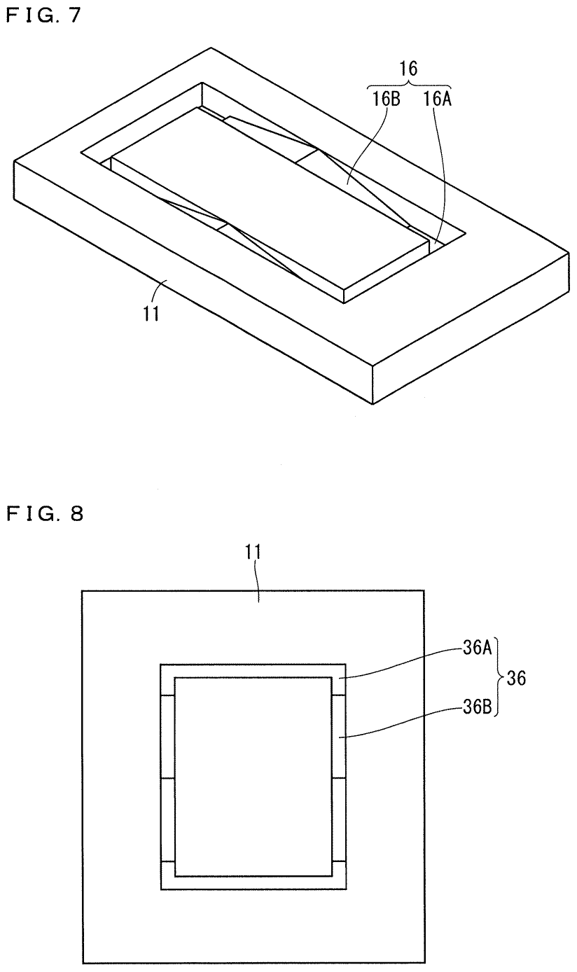

FIG. 7 is a perspective view illustrating a configuration of the cooling plate 11 of a semiconductor device according to the embodiment 3. FIG. 8 is a plan view illustrating a configuration of the cooling plate 11. Although illustration is omitted, a planar shape of the insulating substrate 13 according to the embodiment 3 is similar to that according to the embodiment 1, and is a rectangular shape. The peripheral edge part of the insulating substrate 13 includes two long sides and two short sides.

The cooling plate 11 includes a groove 36. The groove 36 is provided along the whole peripheral edge part of the insulating substrate 13. The groove 36 includes a flat part 36A and an inclination part 36B.

The flat part 36A is provided to be overlapped with the corner part of the insulating substrate 13 in a plan view, and is provided along the short side thereof. The inclination part 36B is provided along only the long side of the insulating substrate 13. In other words, the inclination part 36B is not provided along the short side of the insulating substrate 13.

Although illustration is omitted, the flat part 36A and the inclination part 36B may switched. That is to say, the inclination part 36B may be provided along only the short side of the insulating substrate 13. In this case, the flat part 36A is provided to be overlapped with the corner part of the insulating substrate 13, and is provided along the long side thereof. The inclination part 36B is not provided along the long side of the insulating substrate 13.

As described above, since the inclination part 36B is provide along only any one of the long side and the short side of the insulating substrate 13, the cooling plate 11 is easily processed in the process of manufacturing the semiconductor device.

### Embodiment 4

In an embodiment 4, the same reference numerals are assigned to constituent elements similar to those in any of the embodiments 1 to 3, and the detailed description thereof is omitted.

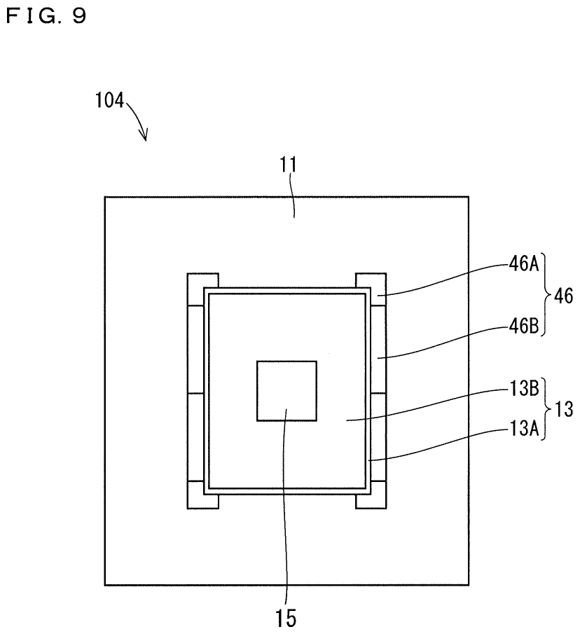

FIG. 9 is a plan view illustrating a configuration of a semiconductor device 104 according to the embodiment 4. Illustration of the first bonding material 12 is omitted in FIG. 9. A planar shape of the insulating substrate 13 is a rectangular shape. The peripheral edge part of the insulating substrate 13 includes two long sides and two short sides.

The cooling plate 11 of the semiconductor device 104 includes a groove 46. The groove 46 is provided along only two long sides and the corner part as a part of the peripheral edge part of the insulating substrate 13. The groove 46 is not provided along two short sides. The groove 46 includes a flat part 46A and an inclination part 46B. The flat part 46A is provided to be overlapped with the corner part of the insulting substrate 13. The inclination part 46B is provided along two long sides.

According to such a configuration, the cooling plate 11 is easily processed in a process of manufacturing the semiconductor device 104.

### Embodiment 5

In an embodiment 5, the same reference numerals are assigned to constituent elements similar to those in any of the embodiments 1 to 4, and the detailed description thereof is omitted.

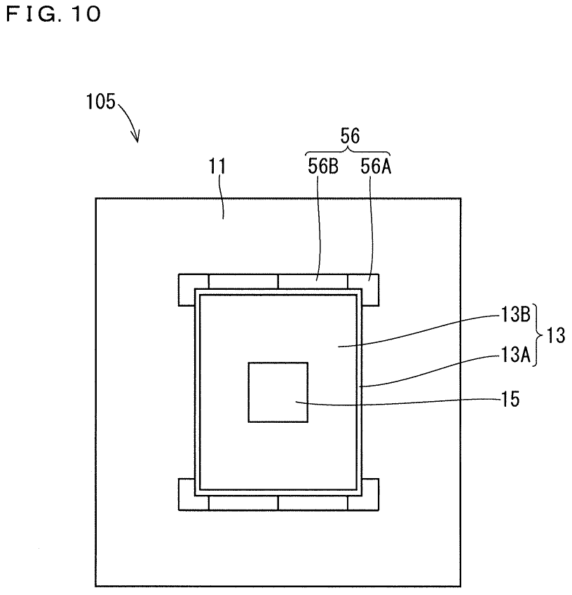

FIG. 10 is a plan view illustrating a configuration of a semiconductor device 105 according to the embodiment 5. Illustration of the first bonding material 12 is omitted in FIG. 10. A planar shape of the insulating substrate 13 is a rectangular shape. The peripheral edge part of the insulating substrate 13 includes two long sides and two short sides.

The cooling plate 11 of the semiconductor device 105 includes a groove 56. The groove 56 is provided along only two short sides and the corner part as a part of the peripheral edge part of the insulating substrate 13. The groove 56 is not provided along two long sides. The groove 56 includes a flat part 56A and an inclination part 56B. The flat part 56A is provided to be overlapped with the corner part of the insulting substrate 13. The inclination part 56B is provided along two short sides.

According to such a configuration, the cooling plate 11 is easily processed in a process of manufacturing the semiconductor device 105.

### Embodiment 6

In an embodiment 6, the same reference numerals are assigned to constituent elements similar to those in any of the embodiments 1 to 5, and the detailed description thereof is omitted.

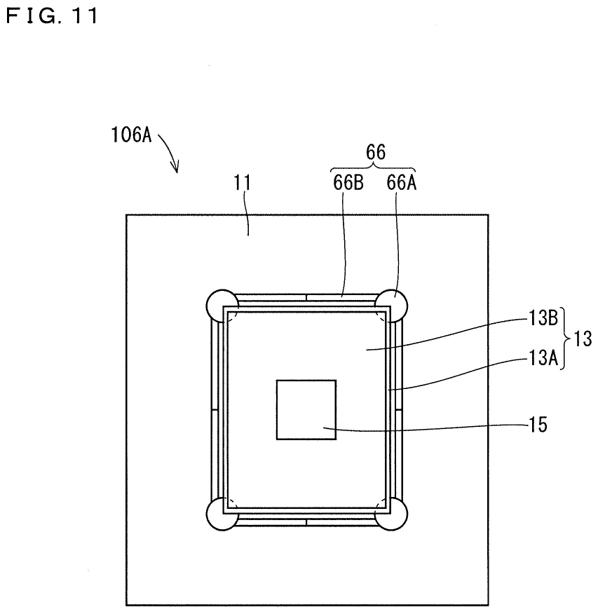

FIG. 11 is a plan view of a configuration of a semiconductor device 106A according to the embodiment 6. Illustration of the first bonding material 12 is omitted in FIG. 11. The cooling plate 11 of the semiconductor device 106A includes a groove 66. The groove 66 is provided along the whole peripheral edge part of the insulting substrate 13. The groove 66 includes a flat part 66A and an inclination part 66B. The flat part 66A is provided to be overlapped with the corner part of the insulting substrate 13 in a plan view. A planar shape of the flat part 66A is a circular shape. The inclination part 66B is provided along the peripheral edge part of the insulating substrate 13 other than the corner part.

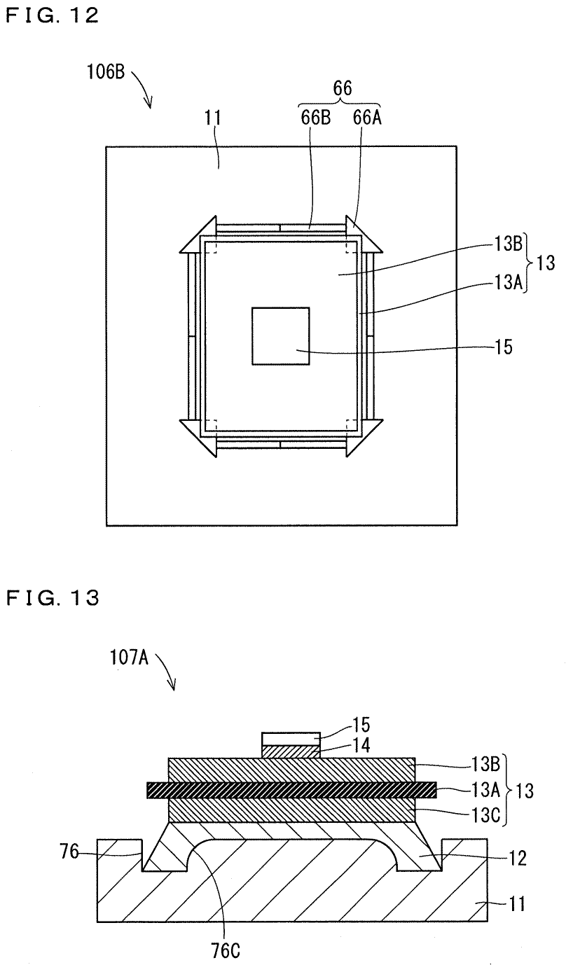

FIG. 12 is a plan view illustrating a configuration of a semiconductor device 106B according to a modification example of the embodiment 6. Illustration of the first bonding material 12 is omitted in FIG. 12. A planar shape of the flat part 66A of the semiconductor device 106B is a triangle shape. A planar shape of the flat part 66A may be a polygonal shape other than the tringle shape.

As described above, the flat part 66A has the circular shape or the polygonal shape in a plan view. The groove 66 having an appropriate shape is disposed in accordance with a design of the semiconductor device.

### Embodiment 7

In an embodiment 7, the same reference numerals are assigned to constituent elements similar to those in any of the embodiments 1 to 6, and the detailed description thereof is omitted.

FIG. 13 is a cross-sectional view illustrating a configuration of the semiconductor device 107A according to the embodiment 7. The cooling plate 11 of the semiconductor device 107A includes a groove 76. A side surface 76C of the groove 76 is curved in a cross-sectional view. The curved side surface 76C corresponds to a side surface located on an inner side in two side surfaces forming the groove 76. According to such a configuration, in a process of manufacturing the semiconductor device 107A, the first bonding material 12 easily flows into the groove 76.

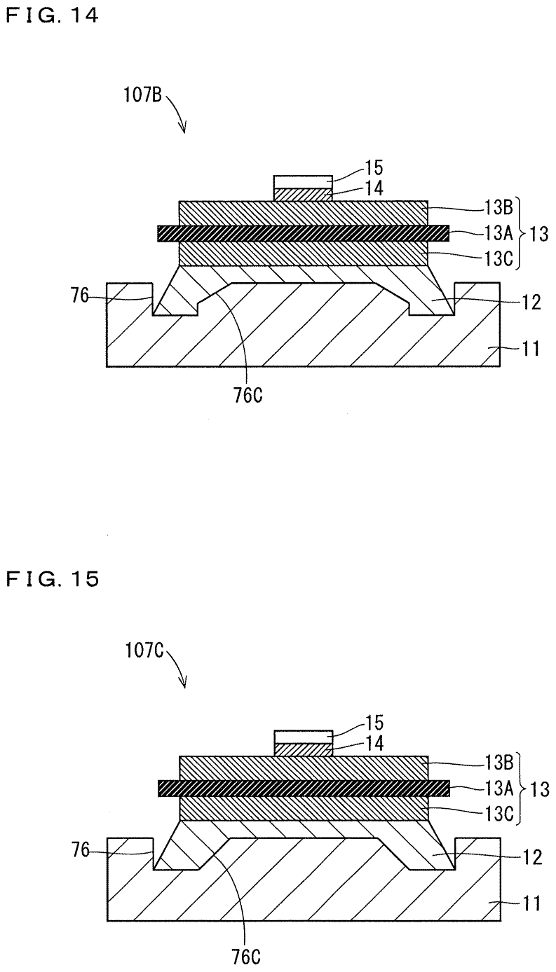

FIG. 14 and FIG. 15 are cross-sectional views each illustrating a configuration of semiconductor devices 107B and 107C according to a modification example of the embodiment 7. A side surface 76C of the groove 76 is inclined in a cross-sectional view. The inclined side surface 76C corresponds to the side surface located on the inner side in two side surfaces forming the groove 76. According to such a configuration, in a process of manufacturing the semiconductor devices 107B and 107C, the first bonding material 12 easily flows into the groove 76.

Although the present disclosure is described above in detail, the foregoing description is in all aspects illustrative and does not restrict the disclosure. It is therefore understood that numerous modification examples not exemplified can be devised.

In the present disclosure, each embodiment can be arbitrarily combined, or each embodiment can be appropriately varied or omitted.

### EXPLANATION OF REFERENCE SIGNS

11 cooling plate, 12 first bonding material, 13 insulating substrate, 13A substrate body, 13B front surface metal pattern, 13C back surface metal pattern, 14 second bonding material, 15 semiconductor chip, 16 groove, 16A flat part, 16B inclination part, 26 groove, 26A flat part, 26B inclination part, 36 groove, 36A flat part, 36B inclination part, 46 groove, 46A flat part, 46B inclination part, 56 groove, 56A flat part, 56B inclination part, 66 groove, 66A flat part, 66B inclination part, 76 groove, 76C side surface, 101 to 107C semiconductor device.

1. A semiconductor device, comprising:
an insulating substrate holding a semiconductor chip; and
a cooling plate holding the insulating substrate, wherein
the cooling plate includes a groove provided along at least a part of a peripheral edge part of the insulating substrate in a plan view,
the groove includes a flat part in which a bottom surface of the groove is flat and an inclination part including a downward inclination in which the bottom surface of the groove is inclined toward the flat part, and
the flat part is provided to be overlapped with a corner part of the insulting substrate included in the peripheral edge part of the insulating substrate in a plan view.

2. The semiconductor device according to claim 1, further comprising
a bonding material bonding the insulating substrate and the cooling plate, wherein
the inclination part is provided along the peripheral edge part of the insulating substrate other than the corner part in a plan view,
the bottom surface of the inclination part includes a top in a midpoint of the inclination part in an extension direction of the groove, and
a part of the bonding material is provided to the groove.

3. The semiconductor device according to claim 1, wherein
a groove width of the flat part is larger than a groove width of the inclination part.

4. The semiconductor device according to claim 1, wherein
the peripheral edge part of the insulating substrate includes a long side and a short side,
the groove is provided along whole the peripheral edge part of the insulting substrate, and
the inclination part is provided along only any one of the long side and the short side of the insulating substrate.

5. The semiconductor device according to claim 1, wherein
the peripheral edge part of the insulating substrate includes a long side and a short side,
the groove is provided along only the long side and the corner part as a part of the peripheral edge part of the insulting substrate, and
the inclination part is provided along the long side.

6. The semiconductor device according to claim 1, wherein
the peripheral edge part of the insulating substrate includes a long side and a short side,
the groove is provided along only the short side and the corner part as a part of the peripheral edge part of the insulting substrate, and
the inclination part is provided along the short side.

7. The semiconductor device according to any one claim 1, wherein
the flat part has a circular shape or a polygonal shape in a plan view.

8. The semiconductor device according to claim 1, wherein
a side surface of the groove is inclined or curved in a cross-sectional view.

9. The semiconductor device according to claim 1, wherein
the semiconductor chip is formed of SiC.
